(19) United States
(12) Patent Application Publication
(10) Pub. No.: US 2024/0040842 A1
(43) Pub. Date: Feb. 1, 2024

(54) DISPLAY APPARATUS

(71) Applicant: Samsung Display Co., Ltd., Yongin-si (KR)

(72) Inventors: Chungi You, Yongin-si (KR); Hyunyoung Kim, Yongin-si (KR)

(21) Appl. No.: 18/126,171

(22) Filed: Mar. 24, 2023

(30) Foreign Application Priority Data
Jul. 28, 2022 (KR) 10-2022-0094027

(51) Int. Cl. H10K 59/122; H10K 59/80; H10K 59/38

(52) U.S. Cl. CPC H10K 59/122; H10K 59/8792; H10K 59/873; H10K 59/871; H10K 59/879; H10K 59/38

(57) ABSTRACT

A display apparatus is presented. The display apparatus includes a lower substrate, an upper substrate, a display layer disposed over the lower substrate, a first anti-reflection layer including a plurality of color filters, and a second anti-reflection layer which is disposed over the first anti-reflection layer and includes a high refractive index layer and a low refractive index layer. The apparatus is sufficiently strong and has reduced reflectivity that a cover member and an optical functional member that are often part of a conventional display apparatus are unnecessary.

### CROSS-REFERENCE TO RELATED APPLICATION

This application is based on and claims priority under 35 U.S.C. § 119 to Korean Patent Application No. 10-2022-0094027 filed on Jul. 28, 2022 in the Korean Intellectual Property Office, the disclosure of which is incorporated by reference herein in its entirety.

### BACKGROUND

### 1. Field

One or more embodiments relate to a structure of a display apparatus.

### 2. Description of the Related Art

Display apparatuses visually display data. Display apparatuses may include a substrate divided into a display area and a peripheral area. A scan line and a data line are mutually insulated from each other in the display area, and a plurality of pixels may be included in the display area. In addition, a thin-film transistor and a pixel electrode electrically connected to the thin-film transistor may be provided in the display area to correspond to each of the pixels. In addition, an opposite electrode commonly provided in the pixels may be provided in the display area. Various lines, which are configured to transfer an electrical signal, a scan driver, a data driver, a controller, a pad unit, or the like may be provided in the peripheral area.

As the usage of display apparatuses has diversified, various designs have been attempted to improve the quality of display apparatuses.

### SUMMARY

A display apparatus offering reduced thickness and a simplified manufacturing process is disclosed. The display apparatus has reduced reflectivity and increased strength such that a separate optical function member and cover member may be omitted. The embodiments that are presented are only examples, and the scope of the disclosure is not limited thereto.

Additional aspects will be set forth in part in the description that follows and, in part, will be apparent from the description, or may be learned by practice of the embodiments of the disclosure.

According to an aspect, a display apparatus includes a lower substrate including a display area and a non-display area, the non-display area surrounding the display area, an upper substrate disposed on the lower substrate, a display layer which is disposed on the lower substrate and includes a plurality of display elements and a bank layer, the bank layer including a first opening defining an emission area for each of the plurality of display elements, a first anti-reflection layer which is disposed between the upper substrate and the display layer, the first anti-reflection layer including a plurality of color filters positioned to correspond to emission areas of the plurality of display elements, and a second anti-reflection layer disposed on the first anti-reflection layer and including at least one high refractive index layer and at least one low refractive index layer, the at least one low refractive index layer having a refractive index less than a refractive index of the at least one high refractive index layer.

The display apparatus may further include an encapsulation layer disposed in the display area to cover the plurality of display elements, and continuously extending into the non-display area, and a sealing member which is located between the lower substrate and the upper substrate and bonds the lower substrate and the upper substrate together in the non-display area, wherein the sealing member is disposed on the encapsulation layer.

The encapsulation layer may include a first inorganic encapsulation layer disposed on the plurality of display elements in the display area and the non-display area, a first organic encapsulation layer disposed on the first inorganic encapsulation layer in the display area, and a second inorganic encapsulation layer covering the first organic encapsulation layer and in the display area and the non-display area, wherein the first inorganic encapsulation layer and the second inorganic encapsulation layer are in contact with each other in the non-display area, and the sealing member is arranged on an area in which the first inorganic encapsulation layer and the second inorganic encapsulation layer are in contact with each other.

The display apparatus may further include a filler located between the upper substrate and the encapsulation layer and in an area enclosed by the sealing member.

The filler may include a silicon-based resin material.

The first anti-reflection layer may further include at least one overcoat layer between the plurality of color filters and the filler.

The bank layer may include a light-shielding insulating material.

The second anti-reflection layer may include two or more high refractive index layers and two or more low refractive index layers, and the high refractive index layer and the low refractive index layer may be alternately stacked on each other.

The first anti-reflection layer may be disposed over an inner surface of the upper substrate, and the second anti-reflection layer may be disposed on an outer surface opposite to the inner surface of the upper substrate.

The first anti-reflection layer may further include an upper base layer on the inner surface of the upper substrate, the upper base layer may include a second opening corresponding to the first opening, and the plurality of color filters may fill the second opening.

The second anti-reflection layer may be disposed on a first inner surface of the upper substrate, and the second anti-reflection layer may be located between the upper substrate and the first anti-reflection layer.

A sealing member, which bonds the lower substrate and the upper substrate together, may be disposed on the second anti-reflection layer in the non-display area.

According to another aspect, a display apparatus includes a lower substrate including a display area and a non-display area, the non-display area surrounding the display area, an upper substrate disposed on the lower substrate, a display layer which is disposed on the lower substrate and includes a plurality of display elements and a bank layer, the bank layer including a first opening defining an emission area for each of the plurality of display elements, a first anti-reflection layer which is disposed between the upper substrate and the display layer, the first anti-reflection layer including a plurality of color filters respectively corresponding to emission areas of the plurality of display elements, an encapsulation layer continuously formed in the display area and the non-display area, the encapsulation layer disposed in the display area between the plurality of display elements and the upper substrate, and a sealing member which is located between the lower substrate and the upper substrate and bonds the lower substrate and the upper substrate together in the non-display area, wherein the sealing member is disposed on the encapsulation layer.

The display may further include a second anti-reflection layer disposed on the first anti-reflection layer, wherein the second anti-reflection layer includes at least one high refractive index layer and at least one low refractive index layer, the at least one low refractive index layer having a refractive index less than a refractive index of the at least one low refractive index layer.

The encapsulation layer may include a first inorganic encapsulation layer disposed on the plurality of display elements and in the display area and the non-display area, a first organic encapsulation layer disposed over the first inorganic encapsulation layer and in the display area, and a second inorganic encapsulation layer disposed on the first organic encapsulation layer and in the display area and the non-display area, wherein the first inorganic encapsulation layer and the second inorganic encapsulation layer are in contact with each other in the non-display area, and the sealing member is arranged on an area in which the first inorganic encapsulation layer and the second inorganic encapsulation layer are in contact with each other.

The display apparatus may further include a filler located between the upper substrate and the encapsulation layer and in an area enclosed by the sealing member.

The filler may include a silicon-based resin material.

The first anti-reflection layer may further include at least one overcoat layer between the plurality of color filters and the filler.

The bank layer may include a light-shielding insulating material.

The second anti-reflection layer may include two or more high refractive index layers and two or more low refractive index layers, and the high refractive index layer and the low refractive index layer may be alternately stacked on each other.

The first anti-reflection layer may be disposed on an inner surface of the upper substrate, and the second anti-reflection layer may be disposed on an outer surface opposite to the inner surface of the upper substrate.

The first anti-reflection layer may further include an upper base layer on the inner surface of the upper substrate, the upper base layer may include a second opening corresponding to the first opening, and the plurality of color filters may fill the second opening.

The second anti-reflection layer may be disposed on a first inner surface of the upper substrate, and the second anti-reflection layer may be located between the upper substrate and the first anti-reflection layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a cross-sectional view schematically illustrating the display apparatus, taken along line A-A′ in FIG. 1;

FIG. 3 is a plan view schematically illustrating the display apparatus in FIG. 1;

FIG. 4 is an equivalent circuit diagram schematically illustrating a pixel of a display apparatus according to an embodiment;

FIG. 5A is a cross-sectional view schematically illustrating the display apparatus, taken along V-V′ in FIG. 3, according to an embodiment;

FIG. 5B is a cross-sectional view schematically illustrating the display apparatus, taken along V-V′ in FIG. 3, according to another embodiment;

FIG. 6 is an enlarged cross-sectional view schematically illustrating a second anti-reflection layer in FIG. 5A;

FIG. 7 is a cross-sectional view schematically illustrating a display apparatus according to another embodiment; and

FIG. 8 is a cross-sectional view schematically illustrating a display apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or any variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

One or more embodiments will be described below in more detail with reference to the accompanying drawings. Those elements that are the same or are in correspondence are rendered the same reference numeral regardless of the figure number, and redundant descriptions thereof are omitted.

In an embodiment below, terms such as “first” and “second” are used herein merely to describe a variety of elements, but the elements are not limited by the terms. Such terms are used only for the purpose of distinguishing one element from another element.

In an embodiment below, an expression used in the singular encompasses the expression of the plural, unless it has a clearly different meaning in the context.

In an embodiment below, it will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated or reduced for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the order in which they are presented.

It will be understood that when a layer, region, or element is referred to as being “connected” to another layer, region, or element, it may be “directly connected” to the other layer, region, or element or may be “indirectly connected” to the other layer, region, or element with other layer, region, or element therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element with other layer, region, or element therebetween.

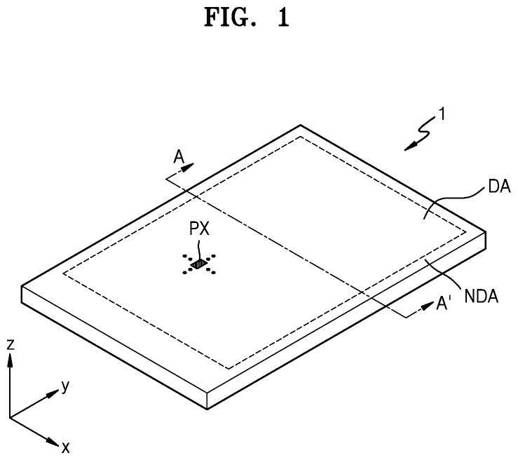

FIG. 1 is a perspective view schematically illustrating a display apparatus 1 according to an embodiment.

Referring to FIG. 1, the display apparatus 1 may display an image. The display apparatus 1 may include a display area DA and a non-display area NDA. A pixel PX may be arranged in the display area DA. The non-display area NDA may at least partially surround the display area DA. The pixel PX may not be arranged in the non-display area NDA. A pad may be arranged in the non-display area NDA.

In FIG. 1, the display apparatus 1 includes the display area DA having a rectangular shape. However, in another embodiment, the display area DA may have a circular shape, an elliptical shape, or a polygonal shape, such as a triangle or pentagon. In addition, in FIG. 1, the display apparatus 1 is a flat panel display apparatus having a flat shape. However, the display apparatus 1 may be implemented in various shapes, such as a flexible, foldable, or rollable display apparatus.

The plurality of pixels PX may be arranged in the display area DA. The plurality of pixels PX may emit light, and the display apparatus 1 may display an image in the display area DA. In an embodiment, the pixel PX may include a plurality of sub-pixels. In an embodiment, any one of the plurality of sub-pixels may emit one of red, green, and blue light. In another embodiment, any one of the plurality of sub-pixels may emit one of red, green, blue, and white light.

The display apparatus 1 according to an embodiment, which displays a moving image or still image, may be used as a display screen of various products, such as televisions, notebook computers, Internet of things (IoT), as well as portable electronic apparatuses, such as mobile phones, smartphones, tablet personal computers (PC), mobile communication terminals, electronic organizers, electronic books, portable multimedia players (PMP), navigations, and ultra-mobile PCs (UMPC). In addition, the display apparatus 1 according to an embodiment may be used in wearable devices, such as smartwatches, watchphones, glasses-type displays, and head-mounted displays (HMD). In addition, the display apparatus 1 according to an embodiment may be used as a center information display (CID) arranged on instrument panels for automobiles, center fascias for automobiles, or dashboards, a room mirror display that replaces side-view mirrors of automobiles, and displays arranged on the rear side of front seats as entertainment for back seats of automobiles.

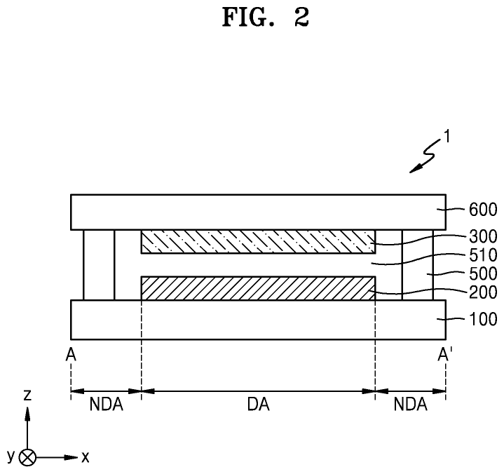

FIG. 2 is a cross-sectional view schematically illustrating the display apparatus 1, taken along line A-A′ in FIG. 1. In FIG. 2, the same reference numerals as those of FIG. 1 denote the same number, and redundant descriptions thereof are omitted.

Referring to FIG. 2, the display apparatus 1 may include a lower substrate 100, a display layer 200, a first anti-reflection layer 300, a sealing member 500, a filler 510, and an upper substrate 600. The display area DA and the non-display area NDA may be defined in the lower substrate 100. In other words, the lower substrate 100 may include the display area DA and the non-display area NDA. In an embodiment, the display area DA may be an area in which the lower substrate 100 and the display layer 200 overlap each other. The non-display area NDA may be an area in which the lower substrate 100 and the display layer 200 do not overlap each other.

The lower substrate 100 may include glass. In another embodiment, the lower substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the lower substrate 100 may have a multi-layer structure including a base layer and a barrier layer (not shown), the base layer including the polymer resin described above. A case in which the lower substrate 100 includes glass is mainly described in detail below.

The display layer 200 may be disposed on the lower substrate 100. In an embodiment, the display layer 200 may overlap the display area DA. In an embodiment, the display layer 200 may include a pixel circuit layer and a display element layer. The pixel circuit layer may include a pixel circuit and an insulating layer. The display element layer may include a display element to be driven by the pixel circuit. In an embodiment, the display element may be an organic light-emitting diode including an organic emission layer. In some embodiments, the display element may be a light-emitting diode (LED) including an inorganic emission layer. The size of the LED may be on a microscale or nanoscale. For example, the LED may be a micro LED. In some embodiments, the LED may be a nanorod LED. The nanorod LED may include gallium nitride (GaN). In an embodiment, a color conversion layer may be disposed on the nanorod LED. The color conversion layer may include quantum dots. In some embodiments, the display element may be a quantum dot LED including a quantum dot emission layer.

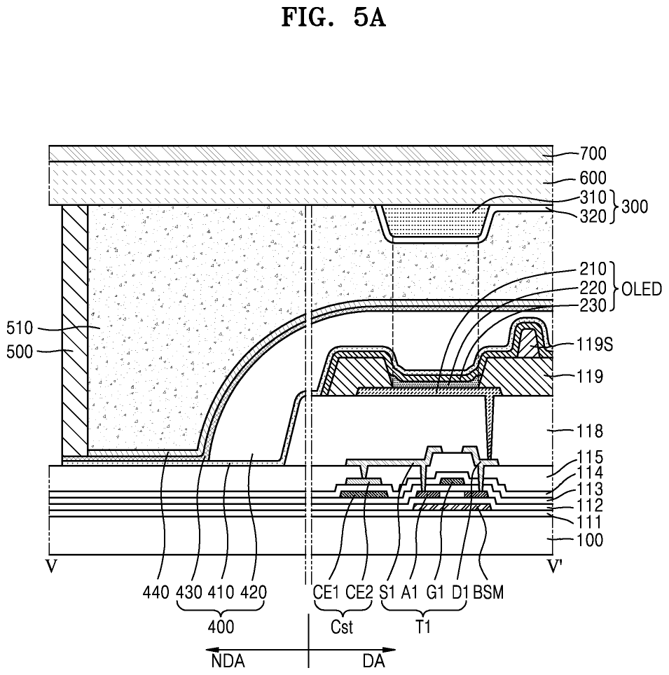

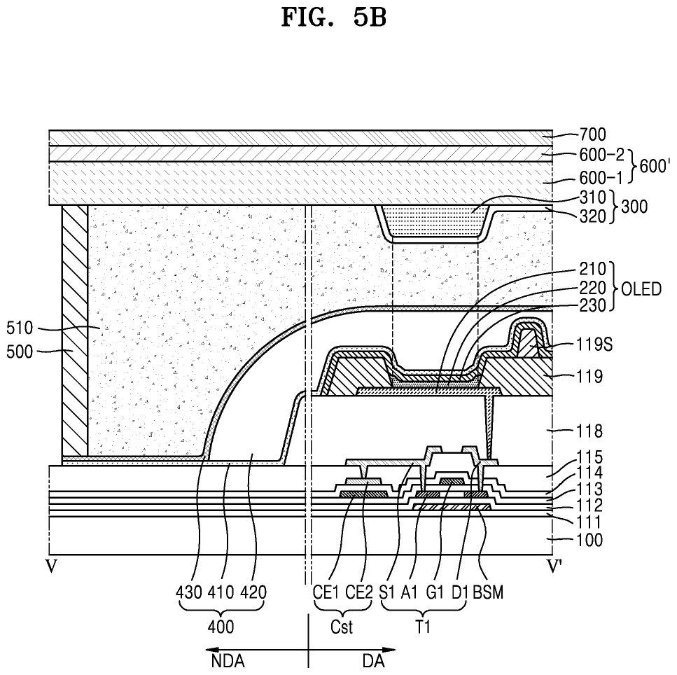

Although not shown in FIG. 2, an encapsulation layer (not shown) may be disposed on the display layer 200. The encapsulation layer may be arranged to cover a plurality of display elements in the display area DA, and extend toward the non-display area NDA. The encapsulation layer may include at least one inorganic encapsulation layer and at least one organic encapsulation layer, both of which cover the display layer 200. The encapsulation layer is described in detail below with reference to FIGS. 5A and 5B.

The upper substrate 600 may be disposed on the display layer 200. In other words, the display layer 200 may be located between the lower substrate 100 and the upper substrate 600. The upper substrate 600 may be a transparent member. In an embodiment, the upper substrate 600 may include glass.

The first anti-reflection layer 300 may be disposed under the upper substrate 600 and on the display layer 200. In other words, the display layer 200 and the first anti-reflection layer 300 may be located between the lower substrate 100 and the upper substrate 600. The first anti-reflection layer 300 may include color filters. The color filters may be arranged by taking account of a color of light emitted by a display element of the display apparatus 1. Each of the color filters may include red, green, or blue pigment or dye. In some embodiments, each of the color filters may further include quantum dots in addition to the pigment or dye described above. In some embodiments, some of the color filters may not include the pigment or dye described above, but may include scattering particles, such as oxide titanium.

The sealing member 500 may be located between the lower substrate 100 and the upper substrate 600. In an embodiment, the sealing member 500 may surround the display area DA and may be arranged in the non-display area NDA. The sealing member 500 may bond the lower substrate 100 and the upper substrate 600 together. In an embodiment, the sealing member 500 may bond the encapsulation layer (not shown), which covers the display layer 200, and the upper substrate 600 together. Accordingly, an inner space between the lower substrate 100 and the upper substrate 600 may be sealed, and an absorbent and/or the filler 510 may be arranged in the inner space.

In an embodiment, the sealing member 500 may be a sealant. For example, the sealing member 500 may include urethane-based resin, epoxy-based resin, and acryl-based resin, which are organic sealants, an inorganic sealant, an organic/inorganic composite sealant, or any combinations thereof. For example, the urethane-based resin may include urethane acrylate or the like. For example, the acryl-based resin may include butyl acrylate, ethylhexyl acrylate, or the like. The inorganic sealant may include a metal, such as silicon, aluminum, titanium, and zirconium, or a metal oxide as a non-metal material. For example, the inorganic sealant may include at least one of titania, silicon oxide, zirconia, alumina, and precursors thereof. Meanwhile, the sealing member 500 may include a material to be cured by heat. The sealing member 500 may replace a material to be cured by laser, such as frit.

In an embodiment, the filler 510 may be arranged in an inner space surrounded by the lower substrate 100, the upper substrate 600, and the sealing member 500. In other words, the filler 510 may be in direct contact with the lower substrate 100, the upper substrate 600, and the sealing member 500. The filler 510 may include a transparent material, such as a silicone-based adhesive material. For example, the filler 510 may include a silicone-based resin material. The filler 510 may be formed by using and thermosetting the silicone-based material described above.

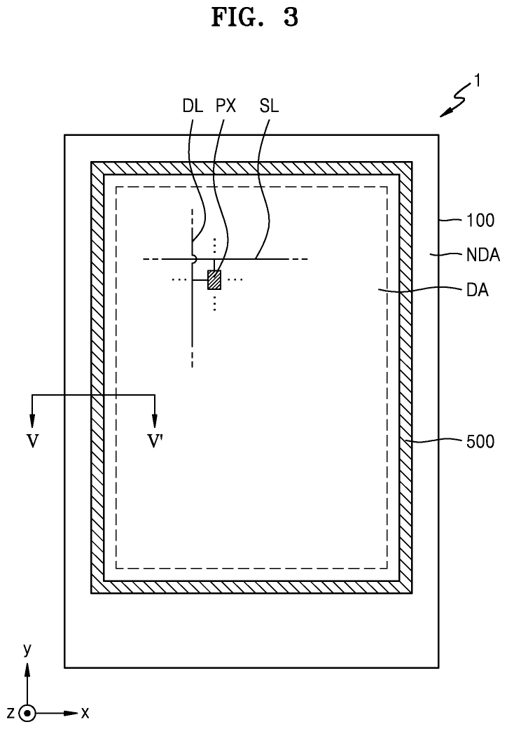

FIG. 3 is a plan view schematically illustrating the display apparatus 1 in FIG. 1. FIG. 3 is a plan view in which the upper substrate 600 is omitted from the display apparatus 1 in FIG. 2. In FIG. 3, the same reference numerals as those of FIG. 2 denote the same member, and redundant descriptions thereof are omitted.

Referring to FIG. 3, the display apparatus 1 may include the lower substrate 100, the pixel PX, a scan line SL, a data line DL, and the sealing member 500. The lower substrate 100 may include the display area DA and the non-display area NDA. The display area DA may be an area of the display apparatus 1 in which an image is displayed. The pixel PX may be arranged in the display area DA. The non-display area NDA may be an area of the display apparatus 1 in which an image is not displayed. A driving circuit and/or power line of the display apparatus 1 may be arranged in the non-display area NDA. In an embodiment, the non-display area NDA may at least partially surround the display area DA. The non-display area NDA may entirely surround the display area DA. The non-display area NDA may include a pad area (not shown). The pad area may be arranged outside the display area DA, and a pad may be arranged in the pad area.

The pixel PX may be arranged in the display area DA. The pixel PX may emit light. In an embodiment, the pixel PX may be provided in plural number, and the display apparatus 1 may display an image by using light emitted from the plurality of pixels PX.

The pixel PX may be electrically connected to the scan line SL and the data line DL, wherein the scan line SL is configured to transfer a scan signal, and the data line DL is configured to transfer a data signal. The pixel PX may receive the scan signal and the data signal and emit light.

The scan line SL may be configured to transfer a scan signal. In an embodiment, the scan line SL may extend in a first direction (e.g., an x direction or −x direction). The scan line SL may be electrically connected to the pixel PX. In an embodiment, the scan line SL may receive a scan signal from a driving circuit (not shown).

The data line DL may transfer a data signal. In an embodiment, the data line DL may extend in a second direction (e.g., a y direction or −y direction). The data line DL may be electrically connected to the pixel PX.

The sealing member 500 may be arranged in the non-display area NDA. In an embodiment, the sealing member 500 may surround the display area DA. In a plan view, the sealing member 500 may partially overlap lines arranged in the non-display area NDA.

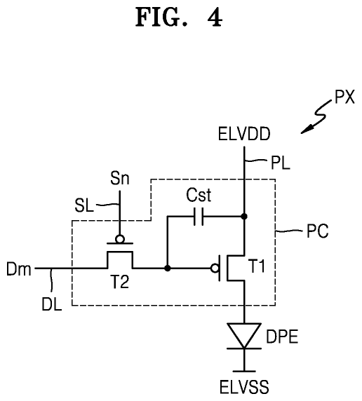

FIG. 4 is an equivalent circuit diagram schematically illustrating a pixel PX of a display apparatus according to an embodiment.

Referring to FIG. 4, the pixel PX may include a pixel circuit PC and a display element DPE electrically connected to the pixel circuit PC. The pixel circuit PC may include a driving thin-film transistor T1, a switching thin-film transistor T2, and a storage capacitor Cst. For example, the pixel PX may emit one of red, green, and blue light or one of red, green, blue, and white light, through the display element DPE.

The switching thin-film transistor T2 may be connected to the scan line SL and the data line DL and may transfer a data voltage or data signal received via the data line DL to the driving thin-film transistor T1 in response to a scan voltage or scan signal received via the scan line SL.

The storage capacitor Cst may be connected to the switching thin-film transistor T2 and a driving voltage line PL and may store a voltage corresponding to a voltage difference between a voltage received from the switching thin-film transistor T2 and a first power voltage ELVDD applied to the driving voltage line PL.

The driving thin-film transistor T1 may be connected to the driving voltage line PL and the storage capacitor Cst, and control a driving current flowing to the display element DPE from the driving voltage line PL to correspond to a voltage value stored in the storage capacitor Cst. The display element DPE may emit light having a certain brightness according to the driving current. An opposite electrode (e.g., the cathode) of the display element DPE may receive a second power voltage ELVSS.

In the embodiment of FIG. 4, the pixel circuit PC includes two thin-film transistors and one storage capacitor. However, in another embodiment, the pixel circuit PC may include three or more thin-film transistors.

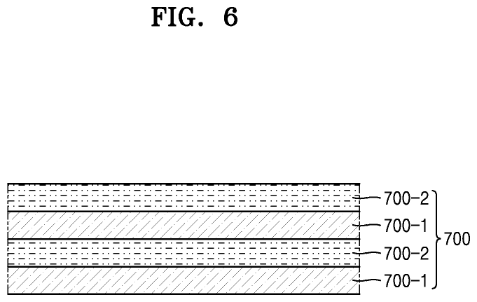

FIG. 5A is a cross-sectional view schematically illustrating the display apparatus, taken along line V-V′ in FIG. 3, according to an embodiment, FIG. 5B is a cross-sectional view schematically illustrating the display apparatus, taken along line V-V′ in FIG. 3, according to another embodiment, and FIG. 6 is an enlarged cross-sectional view schematically illustrating a second anti-reflection layer in FIG. 5A. In FIG. 5, the same reference numerals as those of FIG. 3 denote the same member, and redundant descriptions thereof are omitted.

Referring to FIGS. 5A and 5B, the display apparatus according to an embodiment may include the display area DA and the non-display area NDA outside the display area DA. At least one driving thin-film transistor T1 and a display element connected to the driving thin-film transistor T1 may be disposed on the display area DA. The sealing member 500, a dam (not shown), or the like may be disposed on the non-display area NDA. The display apparatus according to an embodiment is described in detail below, according to a stacked order shown in FIGS. 5A and 5B.

The lower substrate 100 may include a glass material, a ceramic material, a metal material, or a material that is flexible or bendable. When the lower substrate 100 is flexible or bendable, the lower substrate 100 may include polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP). The lower substrate 100 may have a single-layer or multi-layer structure of the material described above, and when the lower substrate 100 has a multi-layer structure, the lower substrate 100 may further include an inorganic layer. In some embodiments, the lower substrate 100 may have a structure of an organic material/inorganic material/organic material.

A barrier layer (not shown) may be further included between the lower substrate 100 and a first buffer layer 111. The barrier layer may prevent or minimize permeation of impurities into a semiconductor layer A1 from the lower substrate 100 or the like. The barrier layer may include an inorganic material, such as an oxide or nitride, an organic material, or an organic and inorganic compound, and may have a single-layer or multi-layer structure of an inorganic material and an organic material.

A bias electrode BSM may be disposed on the first buffer layer 111 to correspond to the driving thin-film transistor T1. A voltage may be applied to the bias electrode BSM. In addition, the bias electrode BSM may prevent external light from reaching the semiconductor layer A1. Thus, the characteristics of the driving thin-film transistor T1 may be stabilized. In some cases, the bias electrode BSM may be omitted.

A second buffer layer 112 may cover the bias electrode BSM and be formed on an entire surface of the lower substrate 100. The second buffer layer 112 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The semiconductor layer A1 may be disposed on the second buffer layer 112. The semiconductor layer A1 may include amorphous silicon or polysilicon. In another embodiment, the semiconductor layer A1 may include an oxide of at least one of indium (In), gallium (Ga), stannum (Sn), zirconium (Zr), vanadium (V), hafnium (Hf), cadmium (Cd), germanium (Ge), chrome (Cr), titanium (Ti), aluminum (Al), cesium (Cs), cerium (Ce), and zinc (Zn). In some embodiments, the semiconductor layer A1 may include a Zn oxide-based material, such as a Zn oxide, an In—Zn oxide, or a Ga—In—Zn oxide. In another embodiment, the semiconductor layer A1 may include an In—Ga—Zn—O (IGZO), In—Sn—Zn—O (ITZO), or In—Ga—Sn—Zn—O (IGTZO) semiconductor, in which a metal, such as indium (In), gallium (Ga), or stannum (Sn), is included in ZnO. The semiconductor layer A1 may include a channel region, a source region, and a drain region, the source region and the drain region being at opposite sides of the channel region. The semiconductor layer A1 may include one or more layers.

A gate electrode G1 may be disposed on the semiconductor layer A1 to at least partially overlap the semiconductor layer A1 with a first insulating layer 113 therebetween. The gate electrode G1 may include molybdenum (Mo), Al, copper (Cu), Ti, or the like, and may include a layer or layers. For example, the gate electrode G1 may be a single Mo layer. A first electrode CE1 of the storage capacitor Cst may be arranged on a same layer on which the gate electrode G1 is disposed. The first electrode CE1 may include a same material as the gate electrode G1.

A second insulating layer 114 may be disposed to cover the gate electrode G1 and the first electrode CE1 of the storage capacitor Cst. The first insulating layer 113 and the second insulating layer 114 may include an inorganic material including an oxide or nitride. For example, the first insulating layer 113 and the second insulating layer 114 may include SiO₂, SiNₓ, SiON, Al₂O₃, TiO₂, Ta₂O₅, HfO₂, or ZnO₂.

A second electrode CE2 of the storage capacitor Cst may be disposed on the second insulating layer 114 to overlap the first electrode CE1 of the storage capacitor Cst. The second electrode CE2 may include Mo, Cu, Ti, or the like, and may include a layer or layers.

An interlayer insulating layer 115 may be provided to cover the second electrode CE2 of the storage capacitor Cst. The interlayer insulating layer 115 may include SiO₂, SiNₓ, SiON, Al₂O₃, TiO₂, Ta₂O₅, HfO₂, ZnO₂, or the like.

A source electrode S1 and a drain electrode D1 may be disposed on the interlayer insulating layer 115.

The source electrode S1 and the drain electrode D1 may include a conductive material, including Mo, Al, Cu, Ti, or the like, and may include a layer or layers including the above-described material. For example, the source electrode S1 and the drain electrode D1 may have a multi-layer structure of a Ti layer, an Al layer, and another Ti layer. The source electrode S1 and the drain electrode D1 may be respectively connected to the source region and the drain region of the semiconductor layer A1 through a contact hole.

The source electrode S1 and the drain electrode D1 may be covered by a planarization layer 118, and an organic light-emitting diode OLED may be disposed on the planarization layer 118.

The planarization layer 118 may include a layer or layers of an organic material and provide a flat upper surface. The planarization layer 118 may include a general-purpose polymer (e.g., benzocyclobutene (BCB), polyimide, hexamethyldisiloxane (HMDSO), polymethylmethacrylate (PMMA), or polystyrene (PS)), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and any blends thereof.

In the display area DA of the lower substrate 100, the organic light-emitting diode OLED may be disposed on the planarization layer 118. The organic light-emitting diode OLED may include a pixel electrode 210 (or a first electrode), an intermediate layer 220, which includes an organic emission layer, and an opposite electrode 230 (or a second electrode).

The pixel electrode 210 may be a (semi-)transmissive electrode or a reflective electrode. In some embodiments, the pixel electrode 210 may include a reflective layer, which includes silver (Ag), magnesium (Mg), Al, platinum (Pt), palladium (Pd), gold (Au), nickel (Ni), neodymium (Nd), iridium (Ir), Cr, or any compounds thereof, and a transparent or semi-transparent electrode layer formed on the reflective layer. The transparent or semi-transparent electrode layer may include at least one of indium tin oxide (ITO), indium zinc oxide (IZO), ZnO, indium oxide (In₂O₃), indium gallium oxide (IGO), and aluminum zinc oxide (AZO). In some embodiments, the pixel electrode 210 may include an ITO layer, an Ag layer, and another ITO layer.

A bank layer 119 may be disposed on the planarization layer 118, and the bank layer 119 may include an opening corresponding to each of sub-pixels, i.e., a first opening exposing at least a central portion of the pixel electrode 210, in the display area DA, thereby defining an emission area of the pixel. In addition, the bank layer 119 may prevent an arc or the like from occurring at an edge of the pixel electrode 210 by increasing a distance between the edge of the pixel electrode 210 and the opposite electrode 230 over the pixel electrode 210.

The bank layer 119 may include an organic insulating layer. In some embodiments, the bank layer 119 may include an inorganic insulating material, such as silicon nitride, silicon oxynitride, or silicon oxide. In some embodiments, the bank layer 119 may include an organic insulating material and an inorganic insulating material. In an embodiment, the bank layer 119 may include a light-shielding material, such as a light-shielding insulating material, and may be provided in black. The light-shielding material may include a resin or paste, including carbon black, carbon nanotube, or black dye, metal particles, such as Ni, Al, Mo, and any alloys thereof, metal oxide particles (e.g., chrome oxide), or metal nitride particles (e.g., chrome nitride). When the bank layer 119 includes the light-shielding material, external light reflection due to metal structures disposed under the bank layer 119 may be reduced.

The intermediate layer 220 of the organic light-emitting diode OLED may include an organic emission layer. The organic emission layer may include an organic material including a fluorescent or phosphorescent material that emits red, green, blue, or white light. The organic emission layer may be a low-molecular weight organic material or polymer organic material, and a functional layer, such as a hole transport layer (HTL), a hole injection layer (HIL), an electron transport layer (ETL), and an electron injection layer (EIL), may selectively be further disposed under and over the organic emission layer. The intermediate layer 220 may be arranged to correspond to each of a plurality of pixel electrodes 210. However, the disclosure is not limited thereto. The intermediate layer 220 may include a layer that is integral across the plurality of pixel electrodes 210, and various modifications may be made.

The opposite electrode 230 may include a transmissive electrode or a reflective electrode. In some embodiments, the opposite electrode 230 may be a transparent electrode or a semi-transparent electrode and may include a metal thin-film having a low work function, including Li, Ca, LiF/Ca, LiF/Al, Al, Ag, Mg, and any compounds thereof. In addition, a transparent conductive oxide (TCO) layer, such as ITO, IZO, ZnO, or In₂O₃, may be further disposed on the metal thin-film. The opposite electrode 230 may be arranged across the display area DA and the peripheral area NDA and may be disposed on the intermediate layer 220 and the bank layer 119. The opposite electrode 230 may be integrally formed as a single body in the plurality of organic light-emitting diodes OLED to correspond to the plurality of pixel electrodes 210.

A spacer 119S may be further included on the bank layer 119 so as to prevent a mask dent. The spacer 119S may be integrally formed as a single body with the bank layer 119. For example, the spacer 119S and the bank layer 119 may be simultaneously formed in a same process by using a half-tone mask process.

The organic light-emitting diode OLED may be easily damaged by moisture or oxygen from the outside and therefore may be protected by being covered by a thin-film encapsulation layer 400. The thin-film encapsulation layer 400 may cover the display area DA and extend beyond the display area DA. The thin-film encapsulation layer 400 may include at least one organic encapsulation layer and at least one inorganic encapsulation layer. For example, the thin-film encapsulation layer 400 may include a first inorganic encapsulation layer 410, an organic encapsulation layer 420, and a second inorganic encapsulation layer 430.

The first inorganic encapsulation layer 410 may cover the opposite electrode 230 and may include silicon oxide, silicon nitride, and/or silicon trioxynitride. Although not shown, when necessary, other layers, such as a capping layer, may be between the first inorganic encapsulation layer 410 and the opposite electrode 230. Because the first inorganic encapsulation layer 410 is formed along an underlying structure thereof, the upper surface of the first inorganic encapsulation layer 410 may not be flat. The organic encapsulation layer 420 may cover the first inorganic encapsulation layer 410, and an upper surface of the organic encapsulation layer 420 may be approximately flat, unlike the first inorganic encapsulation layer 410. For example, a portion of the organic encapsulation layer 420 that corresponds to the display area DA may have a flat upper surface. The organic encapsulation layer 420 may include at least one material out of PET, PEN, PC, polyethylene sulfonate, polyoxymethylene, polyarylate, and HMDSO. The second inorganic encapsulation layer 430 may cover the organic encapsulation layer 420 and may include silicon oxide, silicon nitride, and/or silicon trioxynitride.

In this case, a lower surface of an end of at least one of the first and second inorganic encapsulation layers 410 and 430 described above may be in direct contact with the lower substrate 100 or the interlayer insulating layer 115. For example, at least one of the first and second inorganic encapsulation layers 410 and 430 may be in direct contact with the lower substrate 100 or the interlayer insulating layer 115 on the non-display area NDA.

Due to the multi-layer structure of the thin-film encapsulation layer 400 described above, even when the thin-film encapsulation layer 400 cracks, the crack may not be connected between the first inorganic encapsulation layer 410 and the organic encapsulation layer 420 or between the organic encapsulation layer 420 and the second inorganic encapsulation layer 430. Thus, the formation of a path through which external moisture or oxygen permeates into the display area DA may be prevented or minimized.

As in the display apparatus in FIG. 5A according to an embodiment, a touch detection layer 440 may be disposed on the thin-film encapsulation layer 400. The touch detection layer 440 may include a plurality of touch electrodes having conductivity. For example, the touch detection layer 440 may use a capacitive method. By using a change in capacitance when an object, such as a user's finger, approaches or contacts a surface of the touch detection layer 440, the touch detection layer 440 may output coordinates of a location where the approach or contact of the object occurs. As in the display apparatus in FIG. 5B according to another embodiment, a touch detection layer 600-2 may be disposed on an upper substrate 600-1 to constitute a touch substrate 600′.

The upper substrate 600 may be disposed on the lower substrate 100 and the thin-film encapsulation layer 400 and face the lower substrate 100. The upper substrate 600 may include a flexible plastic material, such as polyimide, a resin material, or glass.

The first anti-reflection layer 300 may be arranged on an inner surface of the upper substrate 600. The first anti-reflection layer 300 may reduce reflectivity of light (external light) incident toward the display apparatus from the outside. In an embodiment, the first anti-reflection layer 300 may include a plurality of color filters 310 and an overcoat layer 320 covering the color filters 310.

The color filter 310 may overlap the organic light-emitting diode OLED. In an embodiment, the color filter 310 may overlap a first opening of the bank layer 119. In an embodiment, the color filter 310 may be provided in plural number. The color filter 310 may be arranged by taking account of a color of light emitted by the organic light-emitting diode OLED. The color filter 310 may include red, green, or blue pigment or dye. In some embodiments, the color filter 310 may further include quantum dots in addition to the pigment or dye described above. In some embodiments, the color filter 310 may not include the pigment or dye described above, but may include scattering particles, such as titanium oxide. For example, the color filter 310 arranged to correspond to an emission area of a pixel emitting red light may be a red color filter, the color filter 310 arranged to correspond to an emission area of a pixel emitting green light may be a green color filter, and the color filter 310 arranged to correspond to an emission area of a pixel emitting blue light may be a blue color filter.

The color filter 310 may prevent or reduce reflection of light in the display apparatus. For example, when external light reaches the color filter 310, only light of a preset wavelength passes through the color filter 310, and light of other wavelengths is absorbed by the color filter 310. Accordingly, only light of a preset wavelength from among external light incident on the display apparatus passes through the color filter 310, and a portion of the light passing through the color filter 310 is reflected by the opposite electrode 230 and the pixel electrode 210 thereunder and emitted to the outside again. As a result, only a portion of external light incident on a place where the pixel is located is reflected to the outside, thereby reducing external light reflection.

The overcoat layer 320 may be disposed on the plurality of color filters 310. The overcoat layer 320 may planarize an inner surface of the upper substrate 600 on which the plurality of color filters 310 are formed, and may include a transparent resin having insulating properties to prevent the elution of pigment ions. In particular, the overcoat layer 320 may include an organic insulating material, such as silicon-based resin, acryl-based resin, epoxy-based resin, polyimide, and polyethylene. In the disclosure, being transparent may indicate having light-transmitting properties and not having a color corresponding to a wavelength band of visible light.

The lower substrate 100 and the upper substrate 600 may be connected to each other through the sealing member 500. In this case, the sealing member 500 may be arranged to surround the display area DA of the display apparatus 1. For example, in a plan view, the sealing member 500 may be arranged outside the display area DA and form a closed loop. In an embodiment, the sealing member 500 may be provided as a sealant. The sealing member 500 may be disposed on the thin-film encapsulation layer 400 in a process of bonding the lower substrate 100 and the upper substrate 600 together. For example, the first inorganic encapsulation layer 410 and the second inorganic encapsulation layer 430 may be in contact with each other in the non-display area NDA, and the sealing member 500 may be disposed on an area in which the first inorganic encapsulation layer 410 and the second inorganic encapsulation layer 430 are in contact with each other. In some embodiments, the sealing member 500 may be disposed on the first inorganic encapsulation layer 410, and the first inorganic encapsulation layer 410 and the sealing member 500 may be in contact with each other inside the sealing member 500. In this case, the sealing member 500 and the upper substrate 600 may completely block the display area DA from the outside.

In an embodiment, the filler 510 may be located between the lower substrate 100 and the upper substrate 600. For example, the filler 510 may be located between the upper substrate 600 and the thin-film encapsulation layer 400, and arranged inside the sealing member 500 having a closed-loop shape in a plan view. Thus, a space on the display area DA side is blocked from the outside by the lower substrate 100, the upper substrate 600, the sealing member 500, and the filler 510, thereby preventing external moisture or impurities from permeating into the display apparatus.

The filler 510 may include a silicon-based resin material. For example, the filler 510 may include an organic material, such as methyl silicone, phenyl silicone, and polyimide. However, the disclosure is not limited thereto, and the filler 510 may include urethane-based resin, epoxy-based resin, and acryl-based resin, which are organic sealants, or silicone, which is an inorganic sealant. Accordingly, the filler 510 may have a high shock absorption coefficient, and thus may buffer against external pressure or the like. In addition, because the filler 510 and the sealing member 500 may protect the display apparatus from internal and external shock, the mechanical strength of the display apparatus may be increased.

In the related art, because the sealing member is provided as frit and the sealing member is not filled with a filler, a separation space filled with a vacuum or gas may be located between the thin-film encapsulation layer 400 and the upper substrate 600. However, the presence of such an air gap may affect the optical path of the light that is generated from the organic light-emitting diode OLED traveling to the outside. This change in optical path may cause a defect (e.g., a rainbow phenomenon) recognized as a stain from the outside, and the mechanical strength of the display apparatus may be relatively weak. However, when the thin-film encapsulation layer 400 and the upper substrate 600 are bonded together by the sealing member 500 and the inner space of the sealing member 500 is filled with the filler 510, as in the display apparatus according to an embodiment, an optical path may be uniform and an image of uniform quality may be implemented, and the mechanical strength of the display apparatus may be increased. In addition, when the mechanical strength of the display apparatus decreases, a shock applied from the outside may be eliminated, and thus, a cover member, such as a cover window, may not be disposed. Thus, in addition to simplifying a manufacturing process of the display apparatus and reducing a manufacturing cost, there is an effect of reducing a thickness of the display apparatus itself.

A second anti-reflection layer 700 may be disposed on the upper substrate 600. The second anti-reflection layer 700 may be disposed on the first anti-reflection layer 300. For example, the first anti-reflection layer 300 may be arranged on an inner surface of the upper substrate 600, and the second anti-reflection layer 700 may be arranged on an outer surface opposite to the inner surface of the upper substrate 600. Similar to the first anti-reflection layer 300, the second anti-reflection layer 700 may reduce reflectivity of light (external light) incident toward the display apparatus from the outside.

In an embodiment, the second anti-reflection layer 700 may be provided by stacking layers having different refractive indices. Referring to FIG. 6, the second anti-reflection layer 700 may include at least one high refractive index layer 700-1 and at least one low refractive index layer 700-2 having a lower refractive index than that of the high refractive index layer 700-1. For example, the second anti-reflection layer 700 may include a plurality of high refractive index layers 700-1 and a plurality of low refractive index layers 700-2, and the high refractive index layer 700-1 and the low refractive index layer 700-2 may be alternately stacked with each other.

The second anti-reflection layer 700 may include an anti-reflection (AR) coating structure. The AR coating structure is a structure that reduces reflectivity by controlling an optical path length. The AR coating structure may cause destructive interference to actively occur by allowing a relative phase shift between light reflected from upper and lower boundaries of a thin-film to be 180 degrees. In the AR coating, an optical path length of the thin-film is preferably an odd integer multiple of λ/4. Here, A may indicate a wavelength optimized for maximum performance or a design wavelength for allowing a path difference between reflected beams to be λ/2. In addition, a refractive index of a thin-film necessary for efficiently canceling reflected light may be calculated by using a refractive index of an upper layer of the thin-film and a refractive index of a lower layer of the thin-film. For example, the high refractive index layer 700-1 may include a material having a refractive index of about 2.3, such as niobium(V) oxide (Nb₂O₅), and the low refractive index layer 700-2 may include a material having a refractive index of about 1.5, such as SiO₂. However, refractive indices of the high refractive index layer 700-1 and the low refractive index layer 700-2 are not limited thereto, and may be freely designed such that destructive interference may occur between the reflected light generated at a layer-by-layer interface.

Consequently, when the second anti-reflection layer 700 is provided, light reflection that may occur at an upper interface of the upper substrate 600 may be reduced. Furthermore, in the display apparatus according to an embodiment, by disposing the first anti-reflection layer 300 under the upper substrate 600 and disposing the second anti-reflection layer 700 on the upper substrate 600, light reflectivity may further be minimized. In the related art, an optical functional member including a polarizer or the like may be disposed to reduce external light reflection. However, the color filter 310 may be disposed under the upper substrate 600 to reduce reflectivity in place of the optical functional member, and thus, the optical function member may not be disposed. As a result, when the optical functional member may be removed, the thickness of the display apparatus may be reduced, and the manufacturing cost of the display apparatus may also be reduced.

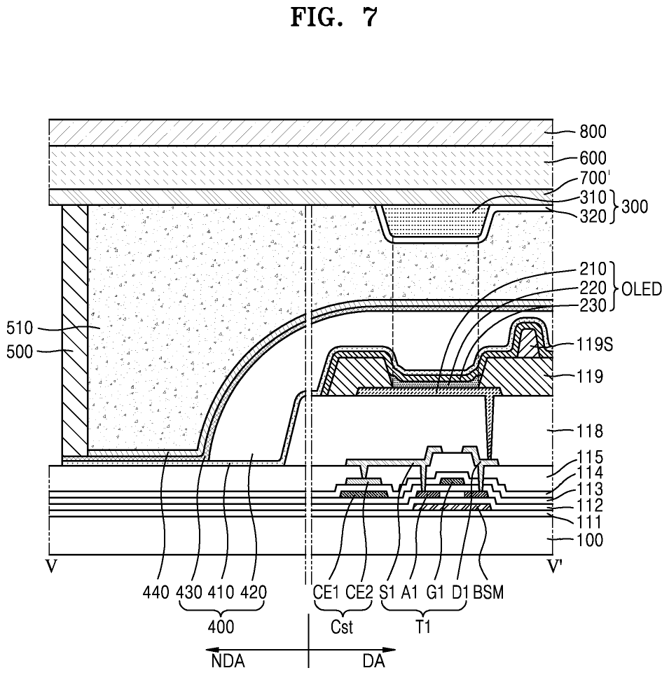

FIG. 7 is a cross-sectional view schematically illustrating a display apparatus according to another embodiment. Referring to FIG. 7, features other than those of a second anti-reflection layer 700′ and a protective film 800 are as described with reference to FIGS. 5A to 6. In FIG. 7, the same characters as those of FIGS. 5A and 6 denote the same member, and thus, only differences are mainly described.

Referring to FIG. 7, the second anti-reflection layer 700′ may be located between the upper substrate 600 and the first anti-reflection layer 300. For example, the second anti-reflection layer 700′ may be disposed on the inner surface of the upper substrate 600 such that an upper surface of the second anti-reflection layer 700′ is in contact with the inner surface of the upper substrate 600, and a lower surface of the second anti-reflection layer 700′ is in contact with the first anti-reflection layer 300. Accordingly, the sealing member 500 bonding the upper substrate 600 and the lower substrate 100 together may be in contact with the second anti-reflection layer 700′ in the non-display area NDA.

The second anti-reflection layer 700′ of the display apparatus according to another embodiment may also be provided by stacking layers having different refractive indices. The second anti-reflection layer 700′ may include at least one high refractive index layer 700-1 (see FIG. 6) and at least one low refractive index layer 700-2 (see FIG. 6), and the high refractive index layer 700-1 and the low refractive index layer 700-2 may be alternately stacked with each other. In other words, because the second anti-reflection layer 700′ includes the AR coating structure, destructive interference may occur between reflected light at a layer-by-layer interface in the second anti-reflection layer 700′, thereby reducing external light reflection. In the display apparatus according to another embodiment, the second anti-reflection layer 700′ primarily reduces external light reflection, and the first anti-reflection layer 300 secondarily reduces external light reflection, so that light reflectivity may be reduced, and thus, the optical functional member may be removed.

Furthermore, the second anti-reflection layer 700′ of the display apparatus according to another embodiment may be located between the upper substrate 600 and the first anti-reflection layer 300. In other words, when the second anti-reflection layer 700′ is arranged within the display apparatus, a separate lamination process may not be performed, after a thin-film process of the high refractive index layer 700-1 and the low refractive index layer 700-2 is performed on the upper substrate 600. Thus, in the display apparatus according to another embodiment, external light reflection may be reduced, and at the same time, a process may be simplified, and a manufacturing process time and a manufacturing cost may be reduced.

When the second anti-reflection layer 700′ is disposed on the inner surface of the upper substrate 600, the protective film 800 may be disposed on an outer surface of the upper substrate 600. The protective film 800 may be attached to protect the upper substrate 600 and an inner portion of the display apparatus from an external shock or object. The protective film 800 may be attached to the entire upper substrate 600 so as to entirely cover the display area DA and the non-display area NDA. The protective film 800 may include a transparent material so that an image provided on a display panel of the display apparatus may be identified even in a state in which the protective film 800 is attached.

When the protective film 800 is disposed on the outer surface of the upper substrate 600, the display apparatus may further be protected safely from external shock. In particular, in the display apparatus according to another embodiment, the sealing member 500 bonds the upper substrate 600 and the thin-film encapsulation layer 400 together, and the inner surface of the sealing member 500 is filled with the filler 510, so that the mechanical strength may be increased, and by further adding the protective film 800, the mechanical strength may be maximized. In other words, in the display apparatus according to another embodiment, a sufficient mechanical strength of the display apparatus may be ensured, and thus, a cover member may not be disposed. Thus, in addition to simplifying a manufacturing process and reducing a manufacturing cost, there is an effect of reducing a thickness of the display apparatus itself.

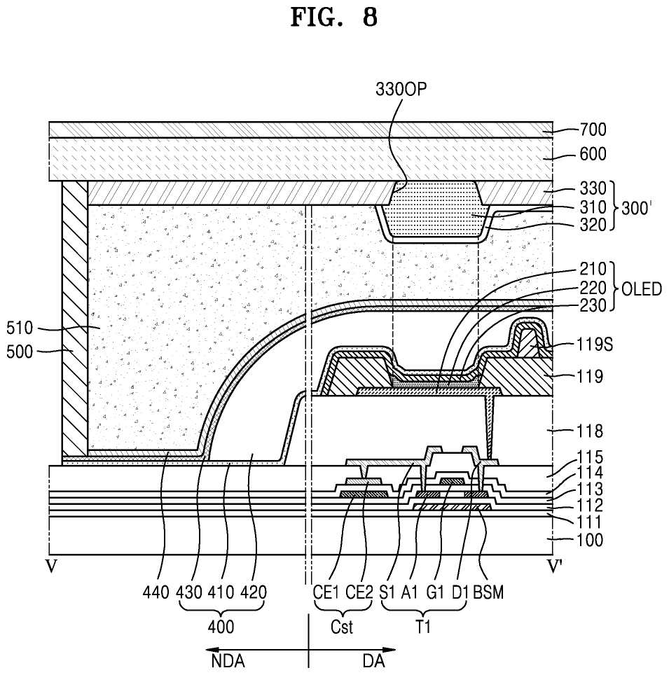

FIG. 8 is a cross-sectional view schematically illustrating a display apparatus according to another embodiment. Referring to FIG. 8, features other than those of a first anti-reflection layer 300′ are as described with reference to FIGS. 5A to 6. In FIG. 8, the same characters as those of FIGS. 5A and 6 denote the same member, and thus, the description will focus on elements that are different from the embodiments of FIG. 5A and FIG. 6.

Referring to FIG. 8, the first anti-reflection layer 300′ may be arranged on an inner surface of the upper substrate 600. The first anti-reflection layer 300′ may include the plurality of color filters 310, an overcoat layer 320, and an upper base layer 330, the overcoat layer 320 covering the color filters 310.

The upper base layer 330 may be disposed on the inner surface of the upper substrate 600 and located between the upper base layer 330 and the overcoat layer 320. The upper base layer 330 may include at least one organic insulating material out of polyimide, polyamide, acrylic resin, BCB, and phenolic resin. However, the upper base layer 330 may include an inorganic insulating material selected from among SiO₂, SiNₓ, Al₂O₃, CuOₓ, Tb₄O₇, Y₂O₃, Nb₂O₅, and Pr₂O₃, as well as the organic insulating material described above. The upper base layer 330 may be provided in a single-layer structure, as shown in FIG. 8. However, the disclosure is not limited thereto, and the upper base layer 330 may be provided in a multi-layer structure of two or more layers. When the upper base layer 330 is provided in a multi-layer structure, the upper base layer 330 may be formed by alternating the organic insulating material and the inorganic insulating material with each other.

In addition, the upper base layer 330 may be provided with a second opening 3300P corresponding to the first opening of the bank layer 119. The plurality of color filters 310 may be arranged to fill the second opening 3300P and overlap the emission area of the organic light-emitting diode OLED and the first opening of the bank layer 119. In other words, the plurality of color filters 310 may have a step difference in a process of being formed on the upper base layer 330 due to the upper base layer 330. Accordingly, a thickness of the color filter 310 in an area of the upper base layer 330 overlapping the second opening 3300P may be greater than a thickness of the color filter 310 in an area of the upper base layer 330 not overlapping the second opening 3300P. As a result, the thickness of the color filter 310 in an area overlapping an emission area of display elements may be increased.

Similar to the display apparatus according to another embodiment, when the thickness of the color filter 310 increases due to the upper base layer 330, an optical path passing through the color filter 310 increases for external light that is incident on the display apparatus, and thus, light transmissivity of external light decreases. This decrease in light transmissivity reduces light reflectivity of the external light. Moreover, when the thickness of the color filter 310 increases, the color filter 310 allows only light of a preset wavelength to pass therethrough, and thus, color purity of light emitted by the organic light-emitting diode OLED may be increased. Consequently, in the display apparatus according to another embodiment, there may be an effect in that external light reflectivity is reduced and at the same time, color matching and color reproducibility are improved.

The display apparatus according to an embodiment configured as described above reduces reflectivity and ensures a sufficient strength of a display panel, allowing an optical functional member and a cover member to be removed or omitted. Accordingly, a process of the display apparatus may be simplified, and a manufacturing cost and the thickness of the display apparatus may be reduced. However, the one or more embodiments are only examples, and the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a lower substrate comprising a display area and a non-display area, the non-display area surrounding the display area;
an upper substrate disposed on the lower substrate;
a display layer which is disposed on the lower substrate and comprises a plurality of display elements and a bank layer, the bank layer comprising a first opening defining an emission area for each of the plurality of display elements;
a first anti-reflection layer which is disposed between the upper substrate and the display layer, the first anti-reflection layer comprising a plurality of color filters positioned to correspond to emission areas of the plurality of display elements; and
a second anti-reflection layer disposed on the first anti-reflection layer and comprising at least one high refractive index layer and at least one low refractive index layer having a refractive index less than a refractive index of the high refractive index layer.

2. The display apparatus of claim 1, further comprising:
an encapsulation layer disposed in the display area to cover the plurality of display elements, and continuously extending into the non-display area; and
a sealing member located between the lower substrate and the upper substrate and bonds the lower substrate and the upper substrate together in the non-display area,
wherein the sealing member is disposed on the encapsulation layer.

3. The display apparatus of claim 2, wherein the encapsulation layer comprises:
a first inorganic encapsulation layer disposed on the plurality of display elements in the display area and the non-display area;
a first organic encapsulation layer disposed on the first inorganic encapsulation layer in the display area; and
a second inorganic encapsulation layer covering the first organic encapsulation layer continuously in the display area and the non-display area,
wherein the first inorganic encapsulation layer and the second inorganic encapsulation layer are in contact with each other in the non-display area, and the sealing member is arranged on an area in which the first inorganic encapsulation layer and the second inorganic encapsulation layer are in contact with each other.

4. The display apparatus of claim 2, further comprising a filler located between the upper substrate and the encapsulation layer and in an area enclosed by the sealing member.

5. The display apparatus of claim 4, wherein the filler comprises a silicon-based resin material.

6. The display apparatus of claim 4, wherein the first anti-reflection layer further comprises at least one overcoat layer between the plurality of color filters and the filler.

7. The display apparatus of claim 2, wherein the bank layer comprises a light-shielding insulating material.

8. The display apparatus of claim 1, wherein the second anti-reflection layer comprises two or more high refractive index layers and two or more low refractive index layers, and
the high refractive index layer and the low refractive index layer are alternately stacked on each other.

9. The display apparatus of claim 1, wherein the first anti-reflection layer is disposed over an inner surface of the upper substrate, and
the second anti-reflection layer is disposed over an outer surface opposite to the inner surface of the upper substrate.

10. The display apparatus of claim 9, wherein the first anti-reflection layer further comprises an upper base layer on the inner surface of the upper substrate,
the upper base layer comprises a second opening corresponding to the first opening, and
the plurality of color filters fill the second opening.

11. The display apparatus of claim 1, wherein the second anti-reflection layer is disposed on an inner surface of the upper substrate, and
the second anti-reflection layer is located between the upper substrate and the first anti-reflection layer.

12. The display apparatus of claim 11, wherein a sealing member, which bonds the lower substrate and the upper substrate together, is disposed on the second anti-reflection layer in the non-display area.

13. A display apparatus comprising:
a lower substrate comprising a display area and a non-display area, the non-display area surrounding the display area;
an upper substrate disposed on the lower substrate;
a display layer which is disposed on the lower substrate and comprises a plurality of display elements and a bank layer, the bank layer comprising a first opening defining an emission area for each of the plurality of display elements;
a first anti-reflection layer which is disposed between the upper substrate and the display layer, the first anti-reflection layer comprising a plurality of color filters positioned to correspond to emission areas of the plurality of display elements;
an encapsulation layer continuously formed in the display area and the non-display area, the encapsulation layer disposed in the display area between the plurality of display elements and the upper substrate; and
a sealing member which is located between the lower substrate and the upper substrate and bonds the lower substrate and the upper substrate together in the non-display area,
wherein the sealing member is disposed on the encapsulation layer.

14. The display apparatus of claim 13, further comprising a second anti-reflection layer disposed on the first anti-reflection layer,
wherein the second anti-reflection layer comprises at least one high refractive index layer and at least one low refractive index layer, the at least one low refractive index layer having a refractive index less than a refractive index of the at least one low refractive index layer.

15. The display apparatus of claim 13, wherein the encapsulation layer comprises:
a first inorganic encapsulation layer disposed on the plurality of display elements and in the display area and the non-display area;
a first organic encapsulation layer disposed on the first inorganic encapsulation layer in the display area; and
a second inorganic encapsulation layer continuously disposed on the first organic encapsulation layer in the display area and the non-display area,
wherein the first inorganic encapsulation layer and the second inorganic encapsulation layer are in contact with each other in the non-display area, and the sealing member is arranged on an area in which the first inorganic encapsulation layer and the second inorganic encapsulation layer are in contact with each other.

16. The display apparatus of claim 13, further comprising a filler located between the upper substrate and the encapsulation layer and in an area enclosed by the sealing member.

17. The display apparatus of claim 16, wherein the filler comprises a silicon-based resin material.

18. The display apparatus of claim 16, wherein the first anti-reflection layer further comprises at least one overcoat layer between the plurality of color filters and the filler.

19. The display apparatus of claim 13, wherein the bank layer comprises a light-shielding insulating material.

20. The display apparatus of claim 14, wherein the second anti-reflection layer comprises two or more high refractive index layers and two or more low refractive index layers, and
the high refractive index layer and the low refractive index layer are alternately stacked on each other.

21. The display apparatus of claim 14, wherein the first anti-reflection layer is disposed on an inner surface of the upper substrate, and
the second anti-reflection layer is disposed on an outer surface opposite to the inner surface of the upper substrate.

22. The display apparatus of claim 21, wherein the first anti-reflection layer further comprises an upper base layer on the inner surface of the upper substrate,
the upper base layer comprises a second opening corresponding to the first opening, and
the plurality of color filters fill the second opening.

23. The display apparatus of claim 14, wherein the second anti-reflection layer is disposed on an inner surface of the upper substrate, and
the second anti-reflection layer is located between the upper substrate and the first anti-reflection layer.
